(19) United States
(12) Patent Application Publication
(10) Pub. No.: US 2010/0127154 A1
(43) Pub. Date: May 27, 2010

(54) NITRIDE-BASED SEMICONDUCTOR LASER DEVICE AND OPTICAL PICKUP

(75) Inventor: Shingo Kameyama, Ibaraki-shi (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi (JP)

(21) Appl. No.: 12/620,252

(22) Filed: Nov. 17, 2009

(30) Foreign Application Priority Data
Nov. 21, 2008 (JP) 2008-298495
Nov. 10, 2009 (JP) 2009-256642

(51) Int. Cl. G01J 1/20; H01S 5/026

(52) U.S. Cl. 250/201.1; 372/49.01

(57) ABSTRACT

A nitride-based semiconductor laser device includes a facet coating film including an alteration preventing layer formed on a light reflecting side facet of a nitride-based semiconductor element layer and a reflectance control layer formed on the alteration preventing layer. The reflectance control layer is formed by a high refractive index layer and a low refractive index layer which are alternately stacked, the alteration preventing layer is constituted by stacking at least two layers, each of which is formed by a dielectric layer made of a nitride, an oxide or an oxynitride. The alteration preventing layer has a first layer made of a nitride in contact with the light reflecting side facet, and a thickness of each of the layers constituting the alteration preventing layer is smaller than that of the high refractive index layer and is smaller than that of the low refractive index layer.

### CROSS-REFERENCE TO RELATED APPLICATIONS

The priority application number JP2008-298495, Nitride-Based Semiconductor Laser Device, Nov. 21, 2008, Shingo Kameyama, JP2009-256642, Nitride-Based Semiconductor Laser Device and Optical Pickup, Nov. 10, 2009, Shingo Kameyama, upon which this patent application is based is hereby incorporated by reference.

### BACKGROUND OF THE INVENTION

1. Field of the Invention

The present invention relates to a nitride-based semiconductor laser device and an optical pickup, and more particularly, it relates to a nitride-based semiconductor laser device formed with dielectric multilayer films on cavity facets and an optical pickup.

2. Description of the Background Art

Recently, wavelength shortening and higher output of a laser beam are desired as the light source of a high-density optical disk system, and a blue-violet semiconductor laser, having a lasing wavelength λ of about 405 nm, made of a nitride-based semiconductor material has been developed.

In a conventional nitride-based semiconductor laser device, respective dielectric multilayer films (facet coating films) are so formed on a light emitting side facet and a light reflecting side facet constituting a pair of cavity facets that the light reflecting side facet has a higher reflectance than the light emitting side facet.

In particular, a reflecting film, formed by alternately stacking layers made of two types of dielectric materials among SiO₂, Al₂O₃, Si₃N, ZrO₂ and the like to have an optical film thickness (=thickness×refractive index) of λ/4 is often employed for the facet coating film formed on the light reflecting side facet, in order to obtain a high reflectance. Further, a dielectric layer different from the reflecting film is formed between the reflecting film and the light reflecting side facet in order to prevent separation of the reflecting film or reaction between a nitride-based semiconductor and the reflecting film. Such a nitride-based semiconductor laser device is disclosed in each of Japanese Patent Laying-Open Nos. 2007-059897, 2007-109737 and 2007-243023, for example.

In a nitride-based semiconductor laser device described in the aforementioned Japanese Patent Laying-Open No. 2007-059897, a dielectric film, made of AlxOy, having a thickness of 20 nm and a dielectric film, made of AlxOy, having a thickness of 40 nm are formed on a light reflecting side facet, and a reflecting mirror formed by alternately stacking six SiO₂ each having a thickness of 67 nm and six ZrO₂ each having a thickness of 44 nm is thereafter formed, for example.

In a nitride semiconductor laser device described in the aforementioned Japanese Patent Laying-Open No. 2007-109737, a silicon nitride layer having a thickness of 51 nm is formed on a light reflecting side facet, twelve oxide layers each having a thickness of 69 nm and twelve nitride silicon layers each having a thickness of 51 nm are thereafter alternately formed, and an oxide layer having a thickness of 137 nm is finally formed, for example.

In a nitride semiconductor laser device described in the aforementioned Japanese Patent Laying-Open No. 2007-243023, amorphous aluminum oxide having a thickness of 80 nm is formed on a light reflecting side facet, and then four silicon oxide films each having a thickness of 71 nm and four titanium oxide films each having a thickness of 46 nm are alternately formed, for example.

Also in the conventional nitride-based semiconductor laser device disclosed in each of the aforementioned Japanese Patent Laying-Open Nos. 2007-059897, 2007-109737 and 2007-243023, however, deterioration or separation of the facet coating film on the light reflecting side is disadvantageously easily caused when light output is large. In particular, deterioration of the facet coating film on a side closer to the light reflecting side facet, which has relatively large thermal energy and light energy, disadvantageously easily progresses. When a part of the facet coating film is deteriorated, the deteriorated region where change of a refractive index or increase of light absorption is caused easily peripherally spreads, and optical characteristics of the overall facet coating film are disadvantageously influenced. Consequently, reduction of stability and reliability of operating characteristics of the laser device is disadvantageously reduced.

### SUMMARY OF THE INVENTION

The inventor has found as a result of a deep study that a conventional dielectric multilayer film formed between a reflecting film of a facet coating film and a semiconductor element is formed to have the following structure, so that sufficient reliability can be obtained even during a high-output operation.

In other words, a nitride-based semiconductor laser device according to a first aspect of the present invention comprises a nitride-based semiconductor element layer having a light emitting side facet and a light reflecting side facet, and a facet coating film including an alteration preventing layer formed on the light reflecting side facet and a reflectance control layer formed on the alteration preventing layer, wherein the reflectance control layer is formed by a high refractive index layer and a low refractive index layer which are alternately stacked, the alteration preventing layer is constituted by stacking at least two layers, each of which is formed by a dielectric layer made of a nitride, an oxide or an oxynitride, the alteration preventing layer has a first layer formed by a dielectric layer made of a nitride in contact with the light reflecting side facet, and a thickness of each of the layers constituting the alteration preventing layer is smaller than that of the high refractive index layer and is smaller than that of the low refractive index layer.

In the present invention, the “light emitting side facet” and the “light reflecting side facet” are distinguished from each other through the large-small direction between the strength levels of laser beams emitted from a pair of cavity facets formed on the nitride-based semiconductor laser device. In other words, the light emitting side facet has relatively larger light strength of the laser beam emitted from the facet, and the light reflecting side facet has relatively smaller light strength of the laser beam. In the present invention, the “reflectance control layer” is a wide concept and means a layer substantially reflecting a laser beam. In the present invention, as to the “high refractive index layer” and the “low refractive index layer”, among two types of dielectric layers constituting the reflectance control layer, a layer having a relatively larger refractive index is the high refractive index layer and a layer having a relatively smaller refractive index is the low refractive index layer.

In the nitride-based semiconductor laser device according to the first aspect of the present invention, as hereinabove described, the alteration preventing layer is formed between the light reflecting side facet and the reflectance control layer, whereby a distance between the reflectance control layer and the light reflecting side facet can be increased, and hence thermal energy and light energy acting on the reflectance control layer can be reduced. Consequently, each of the layers constituting the reflectance control layer is difficult to be altered or deteriorated, and hence separation of the facet coating film from the light reflecting side facet and change of a characteristic reflectance of the facet coating film are suppressed also during a high-output operation, and stability and reliability of the operating characteristics of the nitride-based semiconductor laser device can be improved.

At this time, in the alteration preventing layer, a plurality of the layers each having the thickness smaller than that of the high refractive index layer and smaller than that of the low refractive index layer are stacked on the light reflecting side facet. Thus, even when one of the alteration preventing layer is altered or deteriorated on the cavity facet side where deterioration is easily caused, the deterioration is easily stopped on respective interfaces between the respective layers, and hence alteration or deterioration of a surrounding layer can be suppressed. The thickness of each of the layers constituting the alteration preventing layer is set to be small as described above, and hence the alteration preventing layer is difficult to influence an overall reflection property of the facet coating film. Further, even when one layer in the alteration preventing layer is altered or deteriorated as described above, the region is small and hence change of an overall refractive index of the alteration preventing layer is also suppressed. Thus, the overall reflection property of the facet coating film can be difficult to be influenced.

The thickness of each of the layers constituting the alteration preventing layer is small as described above, and hence stress of each of the layers can be kept small. Thus, separation between the respective layers is difficult to be caused, and stress by the thick reflectance control layer formed thereon can be further sufficiently relaxed.

Each of the layers constituting the alteration preventing layer is made of a nitride, an oxide or an oxynitride, and hence alteration of the layers is difficult to further spread around these layers. In particular, in the layers made of nitrides or oxynitrides, oxygen does not come out of the layers, which may be caused in a case of an oxide, and hence the layers made of nitrides or oxynitrides are preferably employed.

Further, the first layer, in contact with the light reflecting side facet, of the alteration preventing layer is constituted by a dielectric layer made of a nitride, whereby oxygen contained in an external atmosphere or the facet coating film can be inhibited from diffusion to the nitride-based semiconductor element layer. Thus, the light reflecting side facet of the nitride-based semiconductor element layer is difficult to be oxidized, and hence nonradiative recombination centers causing absorption of a laser beam and heat generation are difficult to be caused on the light reflecting side facet. Consequently, catastrophic optical damage (COD) on the light reflecting side facet can be suppressed.

In the aforementioned nitride-based semiconductor laser device according to the first aspect, the alteration preventing layer preferably further has a second layer formed by a dielectric layer made of an oxide or an oxynitride in contact with a side of the first layer opposite to the light reflecting side facet. According to this structure, the second layer made of a material having smaller stress than the first layer is in contact with the first layer, and hence stress which the first layer made of a nitride has can be easily relaxed by the second layer in contact with the first layer.

In this case, the alteration preventing layer preferably further has a third layer formed by a dielectric layer made of a nitride in contact with a side of the second layer opposite to the first layer, in addition to the first layer. According to this structure, a plurality of dielectric layers made of nitrides (two of the first and third layers) are included in the alteration preventing layer, and hence oxygen contained in the external atmosphere or the facet coating film can be further inhibited from diffusion to the nitride-based semiconductor element layer. Also when the dielectric layer (second layer) made of an oxide or an oxynitride is further formed between the dielectric layers made of nitrides, oxygen is difficult to be diffused from the dielectric layer made of an oxide or an oxynitride, and hence alteration of the dielectric layer made of an oxide or an oxynitride is suppressed, and alteration of other dielectric layers and oxidation of the light reflecting side facet can be also suppressed.

In the aforementioned nitride-based semiconductor laser device according to the first aspect, the first layer is preferably AlN. According to this structure, a nitride film made of AlN can easily inhibit oxygen contained in the external atmosphere or the facet coating film from diffusion to the nitride-based semiconductor element layer (light reflecting side facet).

In the aforementioned structure of having the third layer, the second layer is preferably Al₂O₃ or AlON. According to this structure, stress applied between the first and third layers made of the nitride film can be relaxed by Al₂O₃ which is an oxide film or AlON which is an oxynitride film, and hence separation between the first and third layers can be suppressed.

In the aforementioned structure of having the third layer, the third layer is preferably AlN. According to this structure, the nitride film made of AlN can easily inhibit oxygen contained in the external atmosphere from diffusion to the second layer. Thus, oxygen contained in the external atmosphere or the facet coating film can be further suppressed from diffusion to the nitride-based semiconductor element layer (light reflecting side facet), and hence the alteration preventing layer can be easily inhibited from separation from the light reflecting side facet.

In the aforementioned structure of having the third layer, the alteration preventing layer further has a fourth layer formed by a dielectric layer made of an oxide in contact with a side of the third layer opposite to the second layer. According to this structure, the reflectance control layer can be easily formed on the surface of the alteration preventing layer on the side opposite to the light reflecting side facet through the fourth layer made of an oxide.

In the aforementioned nitride-based semiconductor laser device according to the first aspect, the facet coating film is preferably formed between the alteration preventing layer and the reflectance control layer, and preferably further includes an interface layer made of an oxide or an oxynitride. According to this structure, a distance between the reflectance control layer and the light reflecting side facet can be increased by a thickness of the interface layer, and hence thermal energy and light energy acting on the reflectance control layer can be reduced. Consequently, each of the layers constituting the reflectance control layer is difficult to be altered. Further, stress applied between the alteration preventing layer and the reflectance control layer can be relaxed by the interface layer, and hence separation between the alteration preventing layer and the reflectance control layer can be suppressed.

In this case, the interface layer is preferably constituted by a layer in contact with the reflectance control layer and a layer in contact with the alteration preventing layer. According to this structure, the interface layer can be formed by employing the material suitable for adhesiveness between the respective layers of the reflectance control layer and the alteration preventing layer, and hence separation between the respective layers of the reflectance control layer and the alteration preventing layer and the interface layer can be suppressed.

In the aforementioned structure in which the interface layer is constituted by the layers in contact with the respective layers of the reflectance control layer and the alteration preventing layer, the layer constituting the interface layer in contact with the reflectance control layer preferably contains the same element as the reflectance control layer. According to this structure, adhesiveness between the layer constituting the interface layer in contact with the reflectance control layer and the reflectance control layer can be easily improved.

In this case, the layer constituting the interface layer in contact with the reflectance control layer is preferably made of SiO₂. According to this structure, the layer capable of improving adhesiveness with the reflectance control layer (the layer constituting the interface layer) can be easily formed.

In the aforementioned structure in which the interface layer is constituted by the layers in contact with the respective layers of the reflectance control layer and the alteration preventing layer, the layer constituting the interface layer in contact with the alteration preventing layer preferably contains the same metal element as the alteration preventing layer. According to this structure, adhesiveness between the layer constituting the interface layer in contact with the alteration preventing layer and the alteration preventing layer can be easily improved.

In this case, the layer constituting the interface layer in contact with the alteration preventing layer is preferably made of Al₂O₃. According to this structure, the layer capable of improving adhesiveness with the alteration preventing layer (the layer constituting the interface layer) can be easily formed, and optical and thermal degradation can be suppressed, and hence reliability of operating characteristics of the nitride-based semiconductor laser device can be further improved.

In the aforementioned structure in which the facet coating film includes the interface layer, the nitride-based semiconductor element layer further preferably has a light emitting layer, and an optical film thickness of the layer constituting the interface layer is preferably set to at least λ/4, where a wavelength of a laser beam emitted by the light emitting layer is λ. According to this structure, reliability of the operating characteristics of the nitride-based semiconductor laser device can be further improved.

In the aforementioned structure in which the facet coating film includes the interface layer, a thickness of the layer constituting the interface layer is preferably larger than a thickness of each of the layers constituting the alteration preventing layer. According to this structure, a distance between the reflectance control layer and the light reflecting side facet can be easily increased.

In the aforementioned nitride-based semiconductor laser device according to the first aspect, each of the layers constituting the alteration preventing layer preferably contains the same metal element. According to this structure, adhesiveness between the respective layers constituting the alteration preventing layer can be improved.

In the aforementioned structure in which the second layer is made of Al₂O₃ or AlON, the second layer is preferably made of AlON, and a nitrogen composition ratio in the second layer made of AlON is preferably larger than an oxygen composition ratio. According to this structure, the dielectric layer (second layer) made of an oxynitride has higher film density than an oxide or a nitride and is in a strong element bonding state, and hence is difficult to be altered. Thus, diffusion of oxygen contained in the external atmosphere or the facet coating film can be further suppressed. A nitrogen composition ratio in AlON is larger than an oxygen composition ratio, and hence the quantity of diffusion of oxygen contained in the second layer to the first layer or the third layer can be suppressed.

In the aforementioned nitride-based semiconductor laser device according to the first aspect, the nitride-based semiconductor element layer preferably further has a light emitting layer, and an optical film thickness of each of the layers formed by the dielectric layers constituting the alteration preventing layer is preferably set to at most λ/4, where a wavelength of a laser beam emitted by the light emitting layer is λ. According to this structure, stress of the alteration preventing layer can be reduced, and hence separation of the respective layers in the alteration preventing layer can be suppressed. Further, the laser beam emitted from the light reflecting side facet is transmitted with no influence of the thickness of the alteration preventing layer to reach the reflectance control layer. Thus, it is possible to easily suppress that the alteration preventing layer influences the reflectance control function of the reflectance control layer set to have a desired reflectance.

In the aforementioned nitride-based semiconductor laser device according to the first aspect, each of the layers formed by the dielectric layers constituting the alteration preventing layer preferably has a thickness in the range of at least about 10 nm and not more than about 30 nm. According to this structure, stress of each of the layers in the alteration preventing layer can be kept small, and hence separation of the respective layers in the alteration preventing layer can be easily suppressed.

In the aforementioned nitride-based semiconductor laser device according to the first aspect, the low refractive index layer is preferably made of an oxide or an oxynitride, and the high refractive index layer is made of a nitride or an oxynitride. According to this structure, oxygen is difficult to be diffused from the low refractive index layer made of an oxide held between the high refractive index layers made of a nitride or an oxynitride. Consequently, alteration of the low refractive index layer can be suppressed and oxidation of the light reflecting side facet can be suppressed.

In the aforementioned nitride-based semiconductor laser device according to the first aspect, optical film thicknesses of the high refractive index layer and the low refractive index layer constituting the reflectance control layer are preferably λ/4. According to this structure, a reflectance of the reflectance control layer can be maximized.

In the aforementioned nitride-based semiconductor laser device according to the first aspect, the low refractive index layer and the high refractive index layer are preferably polycrystalline. According to this structure, an element bonding state is further strengthened in the polycrystalline state, and hence heat radiability of each layer is further improved and light energy and thermal energy are more stable, and hence film quality of each layer is further difficult to be changed.

According to this invention, stability and reliability of the operating characteristics of the nitride-based semiconductor laser device during a high-output operation can be improved.

An optical pickup according to a second aspect of the present invention comprises a nitride-based semiconductor laser device including a nitride-based semiconductor element layer having a light emitting side facet and a light reflecting side facet, and a facet coating film including an alteration preventing layer formed on the light reflecting side facet and a reflectance control layer formed on the alteration preventing layer, an optical system controlling emitted light of the nitride-based semiconductor laser device, and a light detection portion detecting the emitted light, wherein the reflectance control layer is formed by a high refractive index layer and a low refractive index layer which are alternately stacked, the alteration preventing layer is constituted by stacking at least two layers, each of which is formed by a dielectric layer made of a nitride, an oxide or an oxynitride, the alteration preventing layer has a first layer formed by a dielectric layer made of a nitride in contact with the light reflecting side facet, and a thickness of each of the layers constituting the alteration preventing layer is smaller than that of the high refractive index layer and is smaller than that of the low refractive index layer.

This optical pickup according to the second aspect of the present invention comprises the nitride-based semiconductor laser device having the aforementioned structure, and hence separation of the facet coating film from the light reflecting side facet and change of a characteristic reflectance of the facet coating film are suppressed also when the nitride-based semiconductor laser device performs a high-output operation. Accordingly, the optical pickup improving stability and reliability of the operating characteristics of the nitride-based semiconductor laser device can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram for illustrating a structure of a nitride-based semiconductor laser device according to a first embodiment of the present invention;

FIG. 2 is a sectional view taken along the line A-A in FIG. 1;

FIG. 3 is a sectional view for illustrating a structure of a nitride-based semiconductor laser device according to a third embodiment of the present invention;

FIG. 4 is a sectional view for illustrating a structure of a nitride-based semiconductor laser device according to a sixth embodiment of the present invention;

FIG. 5 is a sectional view for illustrating a structure of a nitride-based semiconductor laser device according to a seventh embodiment of the present invention; and

FIG. 6 is a sectional view for illustrating a structure of a nitride-based semiconductor laser device according to an eighth embodiment of the present invention.

FIGS. 7-9 illustrate an optical pickup comprising a laser apparatus according to a ninth embodiment of the present invention.

### DESCRIPTION OF THE PREFERRED EMBODIMENTS EMBODIMENTS

Embodiments of the present invention will be hereinafter described with reference to the drawings.

### First Embodiment

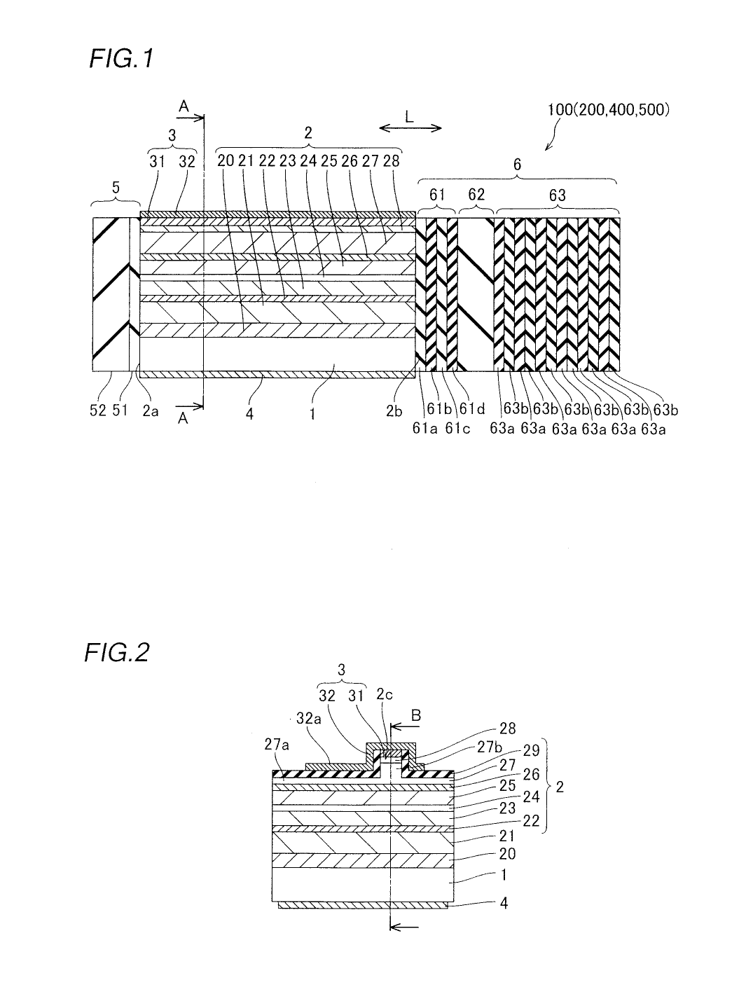

A structure of a nitride-based semiconductor laser device 100 according to a first embodiment of the present invention will be now described with reference to FIGS. 1 and 2. FIG. 1 is a sectional view of the nitride-based semiconductor laser device 100, and shows a section parallel to a laser beam emitting direction (direction L). FIG. 1 shows a section taken along the line B-B in FIG. 2.

The nitride-based semiconductor laser device 100 according to the first embodiment of the present invention has a lasing wavelength λ of about 405 nm and comprises a semiconductor element layer 2, made of a nitride-based semiconductor, formed on an upper surface ((0001) Ga plane) of a substrate 1 made of n-type GaN, a p-side electrode 3 formed on the semiconductor element layer 2 and an n-side electrode 4 formed on a lower surface ((0001) N plane) of the substrate 1, as shown in FIGS. 1 and 2. A light emitting side facet 2a and a light reflecting side facet 2b of the semiconductor element layer 2 formed perpendicular to the laser beam emitting direction (direction L) constitute a pair of cavity facets. The substrate 1 has a thickness of about 100 μm and doped with oxygen having a carrier concentration of about 5×10¹⁸ cm⁻³. The semiconductor element layer 2 formed on the upper surface of the substrate 1 is constituted by an n-type buffer layer 20, an n-type cladding layer 21, an n-type carrier blocking layer 22, an n-side optical guide layer 23, an active layer 24, a p-side optical guide layer 25, a cap layer 26, a p-type cladding layer 27 and a p-side contact layer 28 formed successively on a side closer to the substrate 1, and a current narrowing layer 29 formed on the p-type cladding layer 27. In the first embodiment, the “light emitting layer” in the present invention is constituted by the n-type carrier blocking layer 22, the n-side optical guide layer 23, the active layer 24, the p-side optical guide layer 25 and the cap layer 26.

The n-type buffer layer 20, the n-type cladding layer 21, the n-type carrier blocking layer 22 and the n-side optical guide layer 23 are made of n-type GaN having a thickness of about 100 nm, n-type Al_{0.07}Ga_{0.93}N having a thickness of about 2 μm, n-type Al_{0.16}Ga_{0.84}N having a thickness of about 5 nm and undoped GaN having a thickness of about 100 nm, respectively. Each of the aforementioned n-type layers 20 to 22 is doped with Ge of about 5×10¹⁸ cm⁻³ and has a carrier concentration of about 5×10¹⁸ cm⁻³.

The active layer 24 has an MQW structure in which four barrier layers made of undoped In_{0.02}Ga_{0.98}N each having a thickness of about 20 nm and three well layers made of undoped In_{0.1}Ga_{0.9}N each having a thickness of about 3 nm are alternately stacked.

The p-side optical guide layer 25, the cap layer 26 and the p-side contact layer 28 are made of undoped GaN having a thickness of about 100 nm, undoped Al_{0.16}Ga_{0.84}N having a thickness of about 20 nm and undoped In_{0.02}Ga_{0.98}N having a thickness of about 10 nm, respectively.

The p-type cladding layer 27 is made of p-type Al_{0.07}Ga_{0.93}N, having a carrier concentration of about 5×10¹⁷ cm⁻³, doped with Mg of about 4×10¹⁹ cm⁻³. The p-type cladding layer 27 comprises planar portions 27a each having a thickness of about 80 nm and a projecting portion 27b, protruding from the planar portions 27a, having a height of about 320 nm and a width of about 1.5 μm. The projecting portion 27b is formed in a striped manner, and extends in the direction L ([1-100] direction) perpendicular to the light emitting side facet 2a and the light reflecting side facet 2b. The p-side contact layer 28 is formed only on the projecting portion 27b, and the projecting portion 27b of the p-type cladding layer 27 and the p-side contact layer 28 form a ridge portion 2c. As shown in FIG. 2, the ridge portion 2c is formed on a position closer to a first side surface side from a device center, and the nitride-based semiconductor laser device 100 has an unsymmetrical cross-sectional shape. The current narrowing layer 29, made of SiO₂, having a thickness of about 250 nm is formed on upper surfaces of the planar portions 27a of the p-type cladding layer 27 and side surfaces of the ridge portion 2c.

The p-side electrode 3 consisting of a p-side ohmic electrode 31 formed on the p-side contact layer 28 exposed from the current narrowing layer 29 and a p-side pad electrode 32 formed on the p-side ohmic electrode 31 and the current narrowing layer 29 is formed on the semiconductor element layer 2. The p-side ohmic electrode 31 is made of a Pt layer having a thickness of about 10 nm and a Pd layer having a thickness of about 100 nm formed successively from a side closer to the p-side contact layer 28. The p-side pad electrode 32 is made of a Ti layer having a thickness of about 100 nm and a Pd layer having a thickness of about 100 nm and an Au layer having a thickness of about 3 μm formed successively from a side closer to the p-side ohmic electrode 31 and the current narrowing layer 29. A wire bonding portion 32a of the p-side pad electrode 32 is formed above the planar portions 27a of the p-type cladding layer 27.

The n-side electrode 4 is made of an Al layer having a thickness of about 10 nm, a Pd layer having a thickness of about 20 nm and an Au layer having a thickness of about 300 nm formed successively from the side closer to the substrate 1 on the lower surface of the substrate 1.

A first facet coating film 5 formed by stacking a plurality of dielectric layers is formed on the light emitting side facet 2a. The first facet coating film 5 is constituted by a first alteration preventing layer 51, made of AlN, having a thickness of about 10 nm and a first reflectance control layer 52, made of Al₂O₃, having a thickness of about 82 nm formed successively from a side closer to the light emitting side facet 2a. According to the aforementioned structure, a reflectance of the first facet coating film 5 is set to about 8%.

According to the first embodiment, a second facet coating film 6 formed by stacking a plurality of dielectric layers is formed on the light reflecting side facet 2b. The second facet coating film 6 is constituted by a second alteration preventing layer 61, an interface layer 62, made of SiO₂, having a thickness of about 140 nm and a second reflectance control layer 63 formed successively from a side closer to the light reflecting side facet 2b. An optical film thickness of the interface layer 62 is set to at least λ/4 (when a refractive index of the interface layer 62 is n, a physical film thickness of the interface layer 62 is λ/(4×n)). The second facet coating film 6 is an example of the “facet coating film” in the present invention, and the second alteration preventing layer 61 and the second reflectance control layer 63 are examples of the “alteration preventing layer” and the “reflectance control layer” in the present invention, respectively.

According to the first embodiment, the second alteration preventing layer 61 is constituted by a first layer 61a, made of AlN, having a thickness of about 10 nm, a second layer 61b, made of Al₂O₃, having a thickness of about 10 nm, a third layer 61c, made of AlN, having a thickness of about 10 nm and a fourth layer 61d, made of Al₂O₂, having a thickness of about 10 nm formed successively from the side closer to the light reflecting side facet 2b. The second reflectance control layer 63 has a structure in which six low refractive index layers 63a, made of SiO₂, each having a thickness of about 70 nm and six high refractive index layers 63b, made of ZrO₂, each having a thickness of about 50 nm are alternately stacked in this order from a side closer to the second alteration preventing layer 61. An optical film thickness of each of the first layer 61a to the fourth layer 61d is set to at most λ/4 (when a refractive index of each layer is n, a physical film thickness of each layer is λ/(4×n)). An optical film thickness of each of the low refractive index layers 63a and the high refractive index layers 63b is set to λ/4 (when a refractive index of each layer is n, a physical film thickness of each layer is λ/(4×n)). The first layer 61a, the second layer 61b, the third layer 61c and the fourth layer 61d are each an example of the “dielectric layer” or the “each of layers constituting an alteration preventing layer” in the present invention.

According to the aforementioned structure, a reflectance of the second facet coating film 6 is set to about 98%. The reflectance of the first facet coating film 5 is set to be smaller than the reflectance of the second facet coating film 6, and hence an intensity of a laser beam emitted from the first facet coating film 5 side is larger than an intensity of a laser beam emitted from the second facet coating film 6 side.

A manufacturing process of the nitride-based semiconductor laser device 100 according to the first embodiment of the present invention will be now described.

In the manufacturing process of the nitride-based semiconductor laser device 100, referring to FIGS. 1 and 2, the n-type buffer layer 20, the n-type cladding layer 21, the n-type carrier blocking layer 22, the n-side optical guide layer 23, the active layer 24, the p-side optical guide layer 25, the cap layer 26, the p-type cladding layer 27 having a thickness of about 400 nm and the p-side contact layer 28 are successively formed on the substrate having a thickness of about 400 μm by metal organic vapor phase epitaxy (MOVPE), and p-type annealing treatment is thereafter performed.

Then, the striped p-side ohmic electrodes 31 are formed by vacuum evaporation, and the p-side contact layer 28 and the p-type cladding layer 27 except regions formed with the p-side ohmic electrodes 31 are etched up to a depth of about 320 nm. Thus, the planar portions 27a of the p-type cladding layer 27 each have a thickness of about 80 nm, and the striped ridge portions 2c consisting of the p-type cladding layer 27 and the p-side contact layer 28 is formed. The current narrowing layer 29 is formed on the upper surfaces of the planar portions 27a of the p-type cladding layer 27 and side surfaces of the ridge portion 2c.

The p-side pad electrodes 32 are formed on the p-side ohmic electrodes 31 and the current narrowing layer 29 by vacuum evaporation. The substrate 1 is formed to have a thickness of about 100 μm by polishing the lower surface side of the substrate 1, and the n-side electrode 4 is thereafter formed on the lower surface of the substrate 1 by vacuum evaporation.

The substrate 1 formed with the aforementioned respective layers is cleaved for separation in a direction perpendicular to the extensional direction (direction L) of the striped ridge portions 2c, thereby forming the substrate 1 in a bar state. A pair of cleavage planes parallel to each other obtained by this cleavage step form the light emitting side facet 2a and the light reflecting side facet 2b constituting cavity facets of each laser device.

The first facet coating film 5 and the second facet coating film 6 are formed on the aforementioned cleavage planes.

The aforementioned substrate 1 of the bar state is introduced into an electron cyclotron resonance (ECR) sputtering film forming apparatus, and ECR plasma is applied to the light emitting side facet 2a consisting of the cleavage plane. Thus, the light emitting side facet 2a is cleaned. At this time, the ECR plasma is generated in an N₂ gas atmosphere, and no RF power is applied to the sputtering target.

Thereafter, the first alteration preventing layer 51 made of AlN is formed on the light emitting side facet 2a by ECR sputtering. At this time, sputtering is performed by applying RF power to an Al target while generating the ECR plasma by applying microwave power in Ar and N₂ gas atmosphere.

The first reflectance control layer 52 made of Al₂O₂ is formed on the first alteration preventing layer 51 by ECR sputtering. At this time, sputtering is performed by applying RF power to an Al target while generating the ECR plasma by applying microwave power in Ar and O₂ gas atmosphere.

The light reflecting side facet 2b is cleaned through a cleaning process similar to the cleaning process of the light emitting side facet 2a, and the first layer 61a made of AlN, the second layer 61b made of Al₂O₂, the third layer 61c made of AlN and the fourth layer 61d made of Al₂O₂ are thereafter successively formed on the light reflecting side facet 2b by ECR sputtering. The first layer 61a and the third layer 61c made of AlN are formed under conditions similar to those for the first alteration preventing layer 51 made of AlN. The second layer 61b and the fourth layer 61d made of Al₂O₃ are formed under conditions similar to those for the first reflectance control layer 52 made of Al₂O₃. Thus, the second alteration preventing layer 61 consisting of the first layer 61a to the fourth layer 61d is formed on the light reflecting side facet 2b.

The interface layer 62 made of SiO₂ is formed on the second alteration preventing layer 61 by ECR sputtering. At this time, sputtering is performed by applying RF power to an Si target while generating the ECR plasma by applying microwave power in Ar and O₂ gas atmosphere.

The six low refractive index layers 63a made of SiO₂ and the six high refractive index layers 63b made of ZrO₂ are alternately formed on the interface layer 62 by ECR sputtering. The low refractive index layers 63a made of SiO₂ are formed under conditions similar to those for the interface layer 62 made of SiO₂. When forming the high refractive index layers 63b, sputtering is performed by applying RF power to a Zr target while generating the ECR plasma by applying microwave power in Ar and O₂ gas atmosphere. Thus, the second reflectance control layer 63 consisting of the low refractive index layers 63a and the high refractive index layers 63b is formed on the interface layer 62.

Finally, the substrate 1 of the bar state is separated in a direction parallel to the extensional direction (direction L) of the striped ridge portion 2c, thereby forming the nitride-based semiconductor laser device 100 according to the first embodiment.

According to the first embodiment, as hereinabove described, the second alteration preventing layer 61 is formed between the light reflecting side facet 2b and the second reflectance control layer 63, whereby a distance between the second reflectance control layer 63 and the light reflecting side facet 2b is increased, and hence thermal energy and light energy acting on the second reflectance control layer 63 can be reduced. Consequently, the respective layers 63a and 63b constituting the second reflectance control layer 63 are difficult to be altered or deteriorated, and hence separation of the second facet coating film 6 from the light reflecting side facet 2b and change of a characteristic reflectance of the second facet coating film 6 are suppressed also during a high-output operation, and stability and reliability of the operating characteristics of the nitride-based semiconductor laser device 100 can be improved.

At this time, in the second alteration preventing layer 61, the first layer 61a to the fourth layer 61d each having a thickness smaller than that of each high refractive index layer 63b and smaller than that of each low refractive index layer 63a are stacked on the light reflecting side facet 2b. Thus, even when one of the first layer 61a to the fourth layer 61d constituting the second alteration preventing layer 61 is altered or deteriorated on the light reflecting side facet 2b side where deterioration is easily caused, the deterioration is easily stopped on respective interfaces between the first layer 61a to the fourth layer 61d, and hence alteration or deterioration of a surrounding layer can be suppressed. The thickness of each of the first layer 61a to the fourth layer 61d is set to be small as described above, and hence the second alteration preventing layer 61 is difficult to influence an overall reflection property of the second facet coating film 6. Further, even when one layer in the first layer 61a to the fourth layer 61d constituting the second alteration preventing layer 61 is altered or deteriorated as described above, the region is small and hence change of an overall refractive index of the second alteration preventing layer 61 is also suppressed. Thus, the overall reflection property of the second facet coating film 6 can be also difficult to be influenced.

In particular, the first layer 61a and the third layer 61c are AlN, whereby the nitride films made of AlN can easily inhibit oxygen contained in the external atmosphere or the second facet coating film 6 from diffusion to the light reflecting side facet 2b. The second layer 61b held between the first layer 61a and the third layer 61c is Al₂O₃, whereby stress applied between the first and third layers 61a and 61c made of AlN can be relaxed, and hence separation between the first and third layers 61a and 61c can be suppressed. Further, the fourth layer 61d is Al₂O₃, whereby stress applied between the third layer 61c made of AlN and the interface layer 62 can be relaxed through the fourth layer 61d. Thus, the second alteration preventing layer 61 can be easily inhibited from separation from the light reflecting side facet 2b.

The thickness of each of the first layer 61a to the fourth layer 61d constituting the second alteration preventing layer 61 is small as described above, and hence stress of each of the first layer 61a to the fourth layer 61d can be kept small. Thus, separation between the first layer 61a to the fourth layer 61d is difficult to be caused, and stress by the thick second reflectance control layer 63 formed thereon can be further sufficiently relaxed. The thickness of each of the first layer 61a to the fourth layer 61d is 10 nm and the optical film thickness of each of the layers constituting the second alteration preventing layer 61 is at most λ/4, and hence stress of the second alteration preventing layer 61 can be reduced. Thus, separation of the second alteration preventing layer 61 can be difficult to be caused. Further, the laser beam emitted from the light reflecting side facet 2b is transmitted with no influence of the thickness of each of the first layer 61a to the fourth layer 61d constituting the second alteration preventing layer 61 to reach the second reflectance control layer 63. Thus, it is possible to easily suppress that the second alteration preventing layer 61 influences the reflectance control function of the second reflectance control layer 63 set to have a desired reflectance.

Each of the first layer 61a to the fourth layer 61d constituting the second alteration preventing layer 61 is made of a nitride or an oxide, and hence alteration of each of the first layer 61a to the fourth layer 61d is difficult to further spread around these layers. In particular, in the first layer 61a and the third layer 61c made of nitrides, oxygen does not come out of the layers.

Further, the first layer 61a, in contact with the light reflecting side facet 2b, of the second alteration preventing layer 61 is constituted by a dielectric layer made of a nitride (AlN), whereby oxygen contained in the external atmosphere or the second facet coating film 6 can be inhibited from diffusion to the semiconductor element layer 2. Thus, the light reflecting side facet 2b of the semiconductor element layer 2 is difficult to be oxidized, and hence nonradiative recombination centers causing absorption of a laser beam and heat generation are difficult to be caused on the light reflecting side facet 2b. Consequently, COD on the light reflecting side facet 2b can be suppressed.

According to the first embodiment, the second alteration preventing layer 61 includes the third layer 61c as a dielectric layer made of a nitride (AlN) in addition to the first layer 61a, and hence oxygen contained in the external atmosphere or the second facet coating film 6 can be further inhibited from diffusion to the semiconductor element layer 2. The second layer 61b made of an oxide is formed between the first layer 61a and the third layer 61c made of nitrides, and hence oxygen is difficult to be diffused from the second layer 61b, alteration of the second layer 61b is suppressed, and alteration of other dielectric layers and oxidation of the light reflecting side facet 2b can be also suppressed.

According to the first embodiment, the interface layer 62 made of an oxide (SiO₂) is formed between the second alteration preventing layer 61 and the second reflectance control layer 63, and hence the distance between the second reflectance control layer 63 and the light reflecting side facet 2b can be increased by a thickness of the interface layer 62. Thus, thermal energy and light energy acting on the second reflectance control layer 63 can be reduced, and hence the low refractive index layers 63a and the high refractive index layers 63b constituting the second reflectance control layer 63 are difficult to be altered. Thus, it is possible to suppress that the interface layer 62 influences a light reflection property of the second facet coating film 6. Further, the interface layer 62 can relax stress applied between the second alteration preventing layer 61 and the second reflectance control layer 63, and hence separation between the second alteration preventing layer 61 and the second reflectance control layer 63 can be suppressed. Adhesiveness between the second alteration preventing layer 61 and the second reflectance control layer 63 is improved by the interface layer 62 made of SiO₂, and optical and thermal degradation is suppressed, and hence reliability of operating characteristics of the nitride-based semiconductor laser device 100 can be further improved.

According to the first embodiment, the interface layer 62 in contact with the second reflectance control layer 63 (low refractive index layers 63a) contains the same Si element as the low refractive index layers 63a, whereby adhesiveness between the interface layer 62 and the low refractive index layer 63a can be improved.

According to the first embodiment, the thickness (about 140 nm) of the interface layer 62 is larger than the thickness (about 10 nm) of each of the first layer 61a to the fourth layer 61d constituting the second alteration preventing layer 61, whereby the distance between the second reflectance control layer 63 and the light reflecting side facet 2b can be easily increased.

According to the first embodiment, ZrO₂ easily becoming polycrystalline is employed as the high refractive index layers 63b, and hence heat radiability is improved, light energy and heat energy are more stable, and film quality of the high refractive index layers 63b is difficult to be changed.

According to the first embodiment, the optical film thicknesses of the high refractive index layers 63b and the low refractive index layers 63a constituting the second reflectance control layer 63 are λ/4, and hence a reflectance of the second reflectance control layer 63 can be maximized.

A life test of the nitride-based semiconductor laser device 100 was conducted under a condition of pulse light output of 450 mW (pulse width: 30 nm, duty ratio: 50%, 80° C.). Increase of an operation current was suppressed and mean time to failures (MTTF) of at least 3000 hours was able to be achieved. From the above results, in the nitride-based semiconductor laser device 100 of this embodiment, it has been able to be confirmed that separation of the second facet coating film 6 from the light reflecting side facet 2b and change of the characteristic reflectance of the second facet coating film 6 were suppressed also during a high-output operation, and stability and reliability of the operating characteristics were able to be improved.

### Second Embodiment

Referring to FIG. 1, in a nitride-based semiconductor laser device 200 according to a second embodiment of the present invention, a second layer 61b in a second alteration preventing layer 61 is made of AlOxNy (where x<_{y}) having a thickness of about 30 nm, and a third layer 61c made of AlN has a thickness of about 30 nm.

The second layer 61b made of AlOxNy is formed by sputtering a Zr target by applying RF power to the Zr target while generating ECR plasma by applying microwave power in Ar, O₂ and N₂ gas atmosphere.

The remaining structure and manufacturing process of the nitride-based semiconductor laser device 200 are similar to those of the nitride-based semiconductor laser device 100.

According to the second embodiment, as hereinabove described, the second layer 61b in the second alteration preventing layer 61 is made of an oxynitride (AlOxNy) having a higher film density than an oxide or a nitride. Thus, a bonding state of elements is further strengthened, and hence the layer is difficult to be altered and oxygen contained in an external atmosphere or a second facet coating film 6 can be further inhibited from diffusion.

According to the second embodiment, a nitrogen composition ratio (y) in AlOxNy of the second layer 61b is larger than an oxygen composition ratio (x), and hence the quantity of diffusion of oxygen contained in the second layer 61b to a first layer 61a or the third layer 61c can be suppressed.

The remaining effects of the second embodiment are similar to those of the aforementioned first embodiment. A life test of the nitride-based semiconductor laser device 200 was conducted under a condition similar to that of the aforementioned first embodiment. It has been able to be confirmed that increase of an operation current was suppressed and MTTF of at least 3000 hours was obtained.

### Third Embodiment

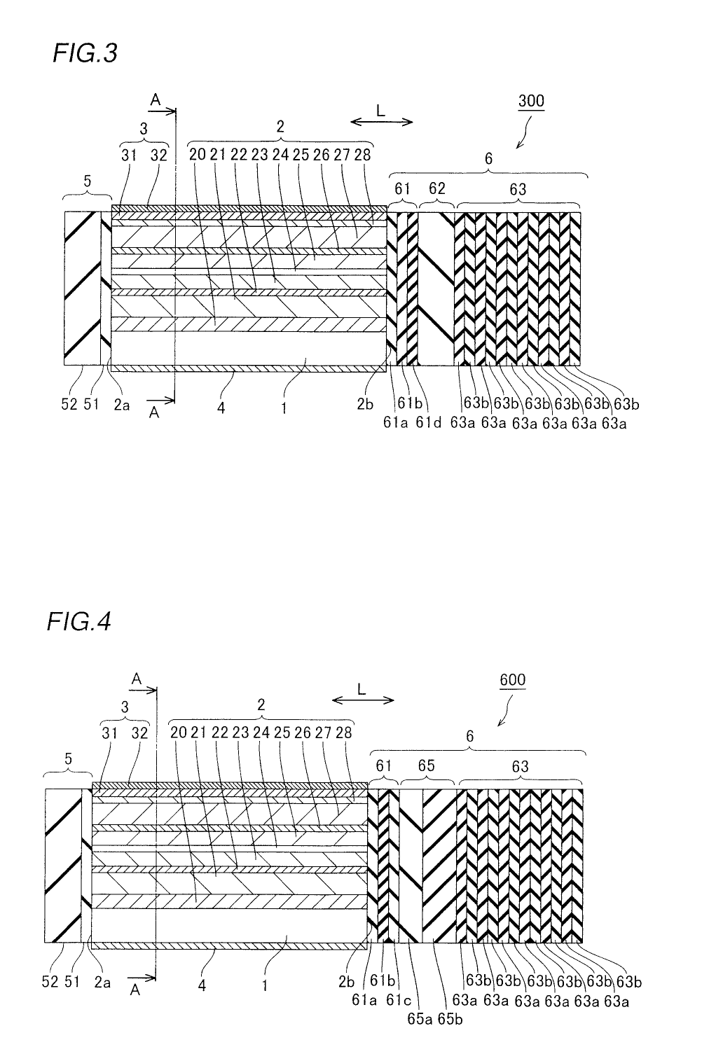

A third embodiment will be described with reference to FIGS. 1 and 3. FIG. 3 is a sectional view for illustrating a structure of a nitride-based semiconductor laser device 300 according to the third embodiment of the present invention, and shows a section parallel to an emission direction of a laser beam. The structure shown in FIG. 3 similar to that shown in FIG. 1 (first embodiment) is denoted by the same reference numerals.

In the nitride-based semiconductor laser device 300 according to the third embodiment of the present invention, a fourth layer 61d is formed directly on a second layer 61b without forming a third layer 61c in a structure of a second alteration preventing layer 61. The remaining structure and manufacturing process of the nitride-based semiconductor laser device 300 are similar to those of the nitride-based semiconductor laser device 200.

According to the third embodiment, as hereinabove described, the second alteration preventing layer 61 is constituted by three layers of the first layer 61a, the second layer 61b and the fourth layer 61d, and hence can be more easily formed as compared with the second alteration preventing layer 61 constituted by four layers in the nitride-based semiconductor laser device 200 (see FIG. 1).

The remaining effects of the third embodiment are similar to those of the aforementioned second embodiment. A life test of the nitride-based semiconductor laser device 300 was conducted under a condition similar to that of the aforementioned first embodiment. It has been able to be confirmed that increase of an operation current was suppressed and MTTF of at least 3000 hours was obtained.

### Fourth Embodiment

Referring to FIG. 1, in a nitride-based semiconductor laser device 400 according to a fourth embodiment of the present invention, high refractive index layers 63b in a second reflectance control layer 63 are each made of AlOxNy (where x<y) having a thickness of about 53 nm.

The high refractive index layers 63b made of AlOxNy are formed under a condition similar to that for the second layer 61b made of AlOxNy of the aforementioned second embodiment. The remaining structure and manufacturing process of the nitride-based semiconductor laser device 400 are similar to those of the nitride-based semiconductor laser device 100.

According to the fourth embodiment, as hereinabove described, each high refractive index layer 63b is made of an oxynitride having a higher film density than a dielectric layer made of an oxide or a nitride. Thus, a bonding state of elements is further strengthened, and hence the layer is difficult to be altered and oxygen contained in an external atmosphere or a second facet coating film 6 can be further inhibited from diffusion.

The remaining effects of the fourth embodiment are similar to those of the aforementioned first embodiment. A life test of the nitride-based semiconductor laser device 400 was conducted under a condition similar to that of the aforementioned first embodiment. It has been able to be confirmed that increase of an operation current was suppressed and MTTF of at least 3000 hours was obtained.

### Fifth Embodiment

Referring to FIG. 1, in a nitride-based semiconductor laser device 500 according to a fifth embodiment of the present invention, high refractive index layers 63b in a second reflectance control layer 63 are each made of AlN having a thickness of about 47 nm. The high refractive index layers 63b made of AlN are formed under a condition similar to that of the first layer 61a made of AlN of the aforementioned first embodiment. The remaining structure and manufacturing process of the nitride-based semiconductor laser device 500 are similar to those of the nitride-based semiconductor laser device 100.

According to the fifth embodiment, as hereinabove described, each high refractive index layer 63b is made of an oxynitride having a higher film density than an oxide. Thus, a bonding state of elements is further strengthened, and hence the layer is difficult to be altered and oxygen contained in an external atmosphere or a second facet coating film 6 can be further inhibited from diffusion.

The remaining effects of the fifth embodiment are similar to those of the aforementioned first embodiment. A life test of the nitride-based semiconductor laser device 500 was conducted under a condition similar to that of the aforementioned first embodiment. It has been able to be confirmed that increase of an operation current was suppressed and MTTF of at least 3000 hours was obtained.

### Sixth Embodiment

A sixth embodiment will be described with reference to FIG. 4. FIG. 4 is a sectional view for illustrating a structure of a nitride-based semiconductor laser device 600 according to the sixth embodiment of the present invention, and shows a section parallel to an emission direction of a laser beam. The structure shown in FIG. 4 similar to that shown in FIG. 1 (first embodiment) is denoted by the same reference numerals.

In the nitride-based semiconductor laser device 600 according to the sixth embodiment of the present invention, a second alteration preventing layer 61 is constituted by three layers of a first layer 61a, a second layer 61b, made of Al₂O₃, having a thickness of about 30 nm and a third layer 61c. Then, an interface layer 65 formed by stacking a plurality of (two) oxide films is formed between the second alteration preventing layer 61 and a second reflectance control layer 63. In other words, in the interface layer 65, a first interface layer 65a, made of Al₂O₃, having a thickness of about 60 nm and a second interface layer 65b, made of SiO₂, having a thickness of about 140 nm are stacked successively from a side closer to a light reflecting side facet 2b on a surface of the second alteration preventing layer 61 (third layer 61c made of AlN). A low refractive index layer 63a made of SiO₂ of the second reflectance control layer 63 is in contact with a surface of the second interface layer 65b on a side opposite to the light reflecting side facet 2b. An optical film thickness of each of the first interface layer 65a and the second interface layer 65b is set to at least λ/4. The first interface layer 65a is an example of the “layer in contact with an alteration preventing layer” in the present invention, and the second interface layer 65b is an example of the “layer in contact with a reflectance control layer” in the present invention.

The remaining structure of the nitride-based semiconductor laser device 600 is similar to that of the nitride-based semiconductor laser device 100. A manufacturing process for the nitride-based semiconductor laser device 600 is similar to that of the nitride-based semiconductor laser device 100 except that the interface layer 65 is formed by stacking the first interface layer 65a made of Al₂O₃ and the second interface layer 65b made of SiO₂ in this order on the second alteration preventing layer 61 by ECR sputtering.

According to the sixth embodiment, as hereinabove described, the interface layer 65 is formed between the second alteration preventing layer 61 and the second reflectance control layer 63, whereby a distance between the second reflectance control layer 63 and the light reflecting side facet 2b is increased and hence thermal energy and light energy acting on the second reflectance control layer 63 is reduced. Therefore, the low refractive index layers 63a and the high refractive index layers 63b constituting the second reflectance control layer 63 can be difficult to be altered.

According to the sixth embodiment, the interface layer 65 is constituted by the first interface layer 65a made of Al₂O₃ and the second interface layer 65b made of SiO₂, and hence stress applied between the second alteration preventing layer 61 and the second reflectance control layer 63 can be sufficiently relaxed. Thus, the second alteration preventing layer 61 and the second reflectance control layer 63 can be inhibited from being separated from each other.

According to the sixth embodiment, the third layer 61c made of AlN of the second alteration preventing layer 61 and the first interface layer 65a are in contact with each other, and the second interface layer 65b and the low refractive index layer 63a made of SiO₂ of the second reflectance control layer 63 are in contact with each other, whereby adhesiveness between the third layer 61c and the first interface layer 65a is excellent due to the same Al element, and adhesiveness between the second interface layer 65b and the low refractive index layer 63a is improved due to SiO₂ films containing the same Si element, and hence the interface layer 65 can reliably inhibit the second alteration preventing layer 61 and the second reflectance control layer 63 from being separated from each other.

The remaining effects of the sixth embodiment are similar to those of the aforementioned first embodiment. A life test of the nitride-based semiconductor laser device 600 was conducted under a condition similar to that of the aforementioned first embodiment. It has been able to be confirmed that increase of an operation current was suppressed and MTTF of at least 3000 hours was obtained.

### Seventh Embodiment

A seventh embodiment will be described with reference to FIG. 5. FIG. 5 is a sectional view for illustrating a structure of a nitride-based semiconductor laser device 700 according to the seventh embodiment of the present invention, and shows a section parallel to an emission direction of a laser beam. The structure shown in FIG. 5 similar to that shown in FIG. 4 (sixth embodiment) is denoted by the same reference numerals.

In the nitride-based semiconductor laser device 700 according to the seventh embodiment of the present invention, a second reflectance control layer 66 has a structure in which seven low refractive index layers 66a, made of SiOxNy (where x<y), having a thickness of about 63 nm and seven high refractive index layers 63b, made of ZrO₂, having a thickness of about 50 nm are alternately stacked. An optical film thickness of each of the low refractive index layers 66a and the high refractive index layers 63b is set to λ/4. Thus, a reflectance of the second facet coating film 6 is set to about 94%. The second reflectance control layer 66 is an example of the “reflectance control layer” in the present invention.

The remaining structure and manufacturing process of the nitride-based semiconductor laser device 700 are similar to those of the nitride-based semiconductor laser device 600.

According to the seventh embodiment, as hereinabove described, each low refractive index layer 66a of the second reflectance control layer 66 is made of a dielectric layer (SiOxNy) made of an oxynitride having a higher film density than a dielectric layer made of an oxide, and hence deterioration of the low refractive index layers 66a itself can be suppressed and oxygen incorporated from an external atmosphere or oxygen from ZrO₂ which is an oxide film constituting the high refractive index layers 63b can be also inhibited from diffusion from the light reflecting side facet 2b to the semiconductor element layer 2.

The remaining effects of the seventh embodiment are similar to those of the aforementioned sixth embodiment. A life test of the nitride-based semiconductor laser device 700 was conducted under a condition similar to that of the aforementioned first embodiment. It has been able to be confirmed that increase of an operation current was suppressed and MTTF of at least 3000 hours was obtained.

### Eighth Embodiment

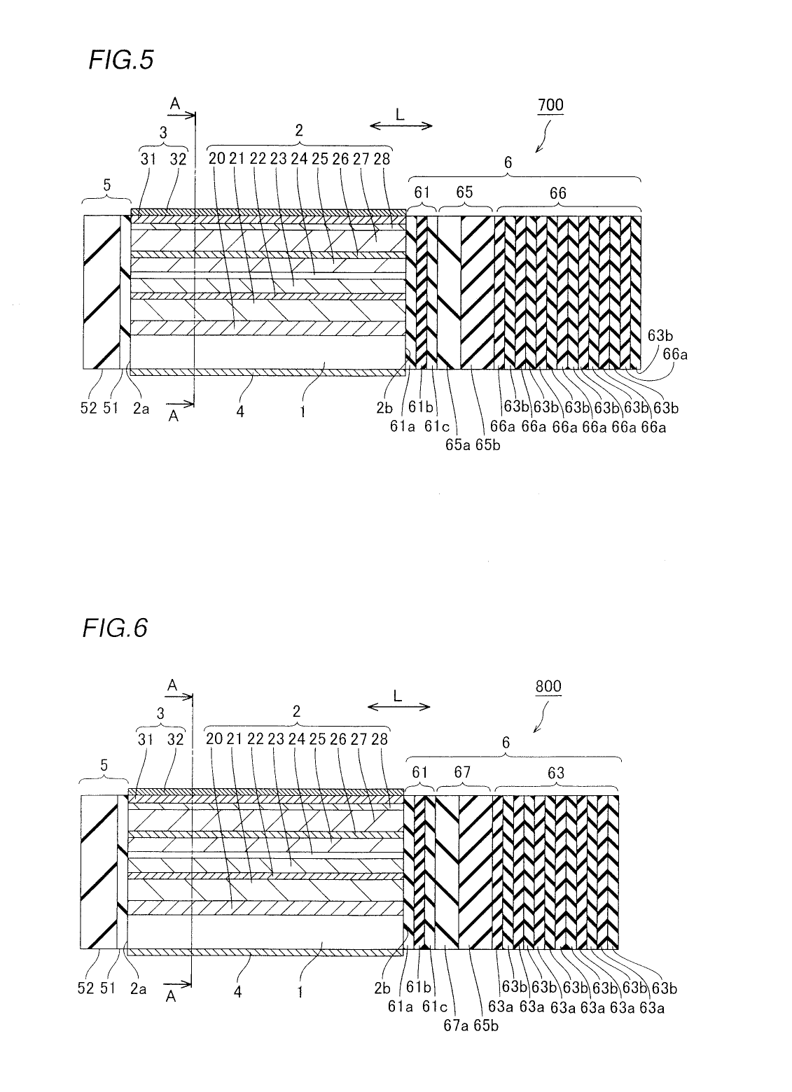

An eighth embodiment will be described with reference to FIG. 6. FIG. 6 is a sectional view for illustrating a structure of a nitride-based semiconductor laser device 800 according to the eighth embodiment of the present invention, and shows a section parallel to an emission direction of a laser beam. The structure shown in FIG. 6 similar to that shown in FIG. 4 (sixth embodiment) is denoted by the same reference numerals.

In the nitride-based semiconductor laser device 800 according to the eighth embodiment of the present invention, an interface layer 67 formed by stacking an oxynitride film and an oxide film is formed between a second alteration preventing layer 61 and a second reflectance control layer 63. In other words, in the interface layer 67, a first interface layer 67a, made of AlOxNy (where x<y), having a thickness of about 53 nm and a second interface layer 65b, made of SiO₂, having a thickness of about 140 nm are stacked successively from a side closer to a light reflecting side facet 2b on a surface of the second alteration preventing layer 61. An optical film thickness of the first interface layer 67a is set to at least λ/4.

The remaining structure and manufacturing process of the nitride-based semiconductor laser device 800 are similar to those of the nitride-based semiconductor laser device 600.

According to the eighth embodiment, as hereinabove described, the first interface layer 67a of the interface layer 67 is made of a dielectric layer (AlOxNy) made of an oxynitride having a higher film density than a dielectric layer made of an oxide, and hence deterioration of the low refractive index layers 66a itself can be suppressed and oxygen incorporated from an external atmosphere or oxygen from SiO₂ which is an oxide film constituting the second interface layer 65b can be also inhibited from diffusion from the light reflecting side facet 2b to the semiconductor element layer 2.

The remaining effects of the eighth embodiment are similar to those of the aforementioned sixth embodiment. A life test of the nitride-based semiconductor laser device 800 was conducted under a condition similar to that of the aforementioned first embodiment. It has been able to be confirmed that increase of an operation current was suppressed and MTTF of at least 3000 hours was obtained.

### Ninth Embodiment

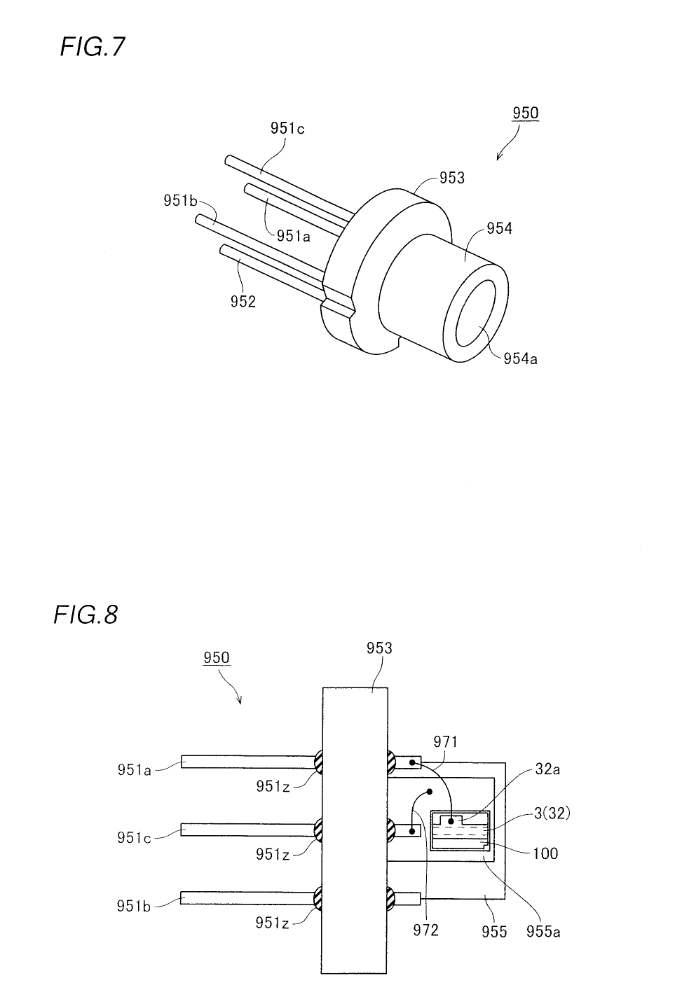

An optical pickup 900 comprising a laser apparatus 950 according to a ninth embodiment of the present invention will be described with reference to FIG. 2 and FIGS. 7 to 9.

The laser apparatus 950 according to the ninth embodiment of the present invention is made of a conductive material, and comprises a substantially rounded can package body 953, power feeding pins 951a, 951b, 951c and 952, and a lid body 954. The can package body 953 is provided with the nitride-based semiconductor laser device 100 according to the aforementioned first embodiment, and is sealed by the lid body 954. The lid body 954 is provided with an extraction window 954a made of a material transmitting a laser beam. The power feeding pin 952 is mechanically and electrically connected to the can package body 953. The power feeding pin 952 is employed as an earth terminal. First ends of the power feeding pins 951a, 951b, 951c and 952, extending outside of the can package body 953 are connected to a operating circuit (not shown).

A conductive submount 955a is provided on a conductive support member 955 integrated with the can package body 953. The support member 955 and the submount 955a are made of excellent conductive and thermal conductive materials. The nitride-based semiconductor laser device 100 is so bonded that an emission direction X of a laser is directed outside (to a side of the extraction window 954a) of the laser apparatus 950 and an emission point (waveguide formed below a ridge 2c shown in FIG. 2) of the nitride-based semiconductor laser device 100 is located on a centerline of the laser apparatus 950.

The power feeding pins 951a, 951b and 951c are electrically insulated from the can package body 953 by the insulating rings 951z. The power feeding pin 951a is connected to an upper surface of a wire bonding portion 32a of a p-side pad electrode 32 (p-side electrode 3) of the nitride-based semiconductor laser device 100 through a wire 971. The power feeding pin 951c is connected to an upper surface of the submount 955a through a wire 972.

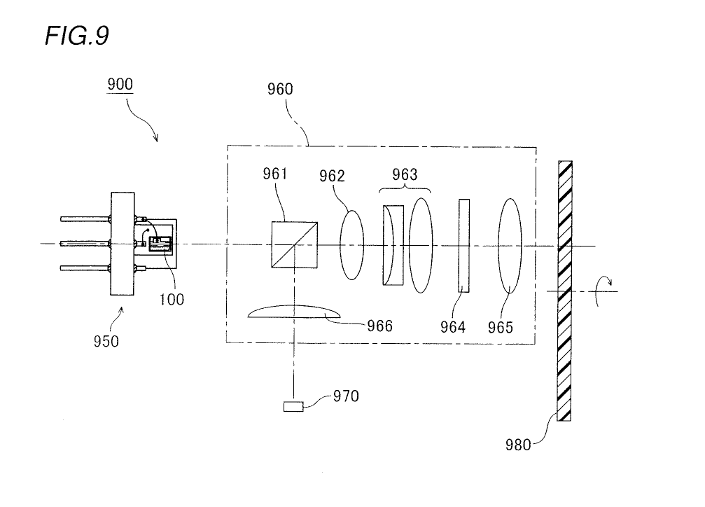

As shown in FIG. 9, the optical pickup 900 comprises an optical system 960 having the laser apparatus 950 mounted with the nitride-based semiconductor laser device 100, a polarizing beam splitter (polarizing BS) 961, a collimator lens 962, a beam expander 963, a λ/4 plate 964, an objective lens 965 and a cylindrical lens 966, and a light detection portion 970.

In the optical system 960, the polarizing BS 961 totally transmits a laser beam emitted from the nitride-based semiconductor laser device 100 and totally reflects the laser beam returned from an optical disc 980. The collimator lens 962 converts the laser beam from the nitride-based semiconductor laser device 100 transmitting through the polarizing BS 961 to parallel light. The beam expander 963 includes a concave lens, a convex lens and an actuator (not shown). The actuator changes a distance of the concave lens and the convex lens in response to a servo signal from the servo circuit (not shown). Thus, a state of wavefront of the laser beam emitted from the nitride-based semiconductor laser device 100 is amended.

The λ/4 plate 964 converts a linearly-polarized laser beam converted to substantially parallel light by the collimator lens 962 to circularly-polarized light. The λ/4 plate 964 converts the circularly-polarized laser beam returned from the optical disc 980 to linearly-polarized light. A direction of polarization of linearly-polarized light in this case is perpendicular to a direction of linear polarization of the laser beam emitted from the nitride-based semiconductor laser device 100. Thus, the laser beam returned from the optical disc 980 is totally reflected by the polarizing BS 961. The objective lens 965 converges the laser beam transmitted through the λ/4 plate 964 on a surface (recording layer) of the optical disc 980. The objective lens 965 is movable in a focus direction, a tracking direction and a tilt direction in response to a servo signal (a tracking servo signal, a focus servo signal and a tilt servo signal) from the servo circuit by an objective lens actuator (not shown).

The cylindrical lens 966 and the light detection portion 970 are arranged along an optical axis of the laser beam totally reflected by the polarizing BS 961. The cylindrical lens 966 gives astigmatic action to an incident laser beam. The light detection portion 970 outputs a reproduced signal on the basis of intensity distribution of a received laser beam. The light detection portion 970 has a prescribed patterned detection region to obtain the reproduced signal as well as a focus error signal, a tracking error signal and a tilt error signal. The actuator of the beam expander 963 and the objective lens actuator are feedback-controlled by the focus error signal, the tracking error signal and the tilt error signal. Thus, the optical pickup 900 according to the ninth embodiment of the present invention is formed.

According to the ninth embodiment, as hereinabove described, the nitride-based semiconductor laser device 100 according to the aforementioned first embodiment is employed in the optical pickup 900, and hence separation of the second facet coating film 6 from the light reflecting side facet 2b and change of a characteristic reflectance of the second facet coating film 6 are suppressed also during a high-output operation. Accordingly, the optical pickup 900 improving stability and reliability of the operating characteristics of the nitride-based semiconductor laser device 100 can be obtained.

Although the present invention has been described and illustrated in detail, it is clearly understood that the same is by way of illustration and example only and is not to be taken by way of limitation, the spirit and scope of the present invention being limited only by the terms of the appended claims.

For example, while the first layer 61a to the fourth layer 61d in the second alteration preventing layer 61 are each made of an oxide, a nitride or an oxynitride of the same element (Al) in each of the aforementioned first to eighth embodiments, the present invention is not restricted to this but each layer may be made of an oxide, a nitride or an oxynitride of a different element. Alternatively, the second alteration preventing layer 61 may have a structure in which no layer made of an oxide is included, in other words, may be formed only by layers each made of a nitride or an oxynitride.

While the second alteration preventing layer 61 consists of three layers or four layers and is formed by a multilayer film of layers made of an oxide, a nitride or an oxynitride in each of the aforementioned first to ninth embodiments, the present invention is not restricted to this but the second alteration preventing layer 61 may be formed by a multilayer film of two or at least five layers.

While the second reflectance control layer 63 has a structure in which the six low refractive index layers 63a and the six high refractive index layers 63b are alternately formed in each of the first to sixth, eighth and ninth embodiments, the present invention is not restricted to this but the second reflectance control layer 63 may be stacked in numbers other than six.

While AlN is employed for a nitride, Al₂O₃, SiO₂ or ZrO₂ is employed for an oxide, AlOxNy and SiOxNy are employed for an oxynitride as the dielectric material constituting each of layers constituting the second facet coating film 6 in each of the aforementioned first to ninth embodiments, the present invention is not restricted to this but a nitride, an oxide or an oxynitride of other metal element may be employed. For example, a nitride such as Si, or an oxide or an oxynitride such as Zr, Ta, Hf and Nb can be employed as each dielectric material.

While the interface layer 62 is formed by employing the oxide film made of SiO₂ in each of the aforementioned first to fifth embodiments, the present invention is not restricted to this but an oxide film containing Zr, Ta, Nb and the like may be employed.

While AlOxNy is employed for the first interface layer 67a constituting the interface layer 67 in the aforementioned eighth embodiment, the present invention is not restricted to this but the first interface layer 67a may be formed by employing an oxynitride film containing Si, Zr, Ta, Hf, Nb and the like.

While the interface layer consisting of a single layer or two layers is formed in each of the aforementioned first to ninth embodiments, the present invention is not restricted to this but the an interface layer may be formed by employing at least three dielectric layers. For example, when the interface layer is formed by three layers, the interface layer is preferably formed by stacking an oxide film, an oxynitride film and an oxide film successively from the alteration preventing layer toward the reflectance control layer.

While each layer of the first facet coating film 5 and the second facet coating film 6 is formed by ECR sputtering in each of the first to ninth embodiments, the present invention is not restricted to this but the layers may be formed by other film forming method.

What is claimed is:

1. A nitride-based semiconductor laser device comprising:
a nitride-based semiconductor element layer having a light emitting side facet and a light reflecting side facet; and
a facet coating film including an alteration preventing layer formed on said light reflecting side facet and a reflectance control layer formed on said alteration preventing layer, wherein
said reflectance control layer is formed by a high refractive index layer and a low refractive index layer which are alternately stacked,
said alteration preventing layer is constituted by stacking at least two layers, each of which is formed by a dielectric layer made of a nitride, an oxide or an oxynitride,
said alteration preventing layer has a first layer formed by a dielectric layer made of a nitride in contact with said light reflecting side facet, and
a thickness of each of the layers constituting said alteration preventing layer is smaller than that of said high refractive index layer and is smaller than that of said low refractive index layer.

2. The nitride-based semiconductor laser device according to claim 1, wherein
said alteration preventing layer further has a second layer formed by a dielectric layer made of an oxide or an oxynitride in contact with a side of said first layer opposite to said light reflecting side facet.

3. The nitride-based semiconductor laser device according to claim 2, wherein
said alteration preventing layer further has a third layer formed by a dielectric layer made of a nitride in contact with a side of said second layer opposite to said first layer, in addition to said first layer.

4. The nitride-based semiconductor laser device according to claim 1, wherein
said first layer is AlN.

5. The nitride-based semiconductor laser device according to claim 3, wherein
said second layer is Al₂O₃ or AlON.

6. The nitride-based semiconductor laser device according to claim 3, wherein
said third layer is AlN.

7. The nitride-based semiconductor laser device according to claim 3, wherein
said alteration preventing layer further has a fourth layer formed by a dielectric layer made of an oxide in contact with a side of said third layer opposite to said second layer.

8. The nitride-based semiconductor laser device according to claim 1, wherein
said facet coating film is formed between said alteration preventing layer and said reflectance control layer, and further includes an interface layer made of an oxide or an oxynitride.

9. The nitride-based semiconductor laser device according to claim 8, wherein
said interface layer is constituted by a layer in contact with said reflectance control layer and a layer in contact with said alteration preventing layer.

10. The nitride-based semiconductor laser device according to claim 9, wherein
the layer constituting said interface layer in contact with said reflectance control layer contains the same element as said reflectance control layer.

11. The nitride-based semiconductor laser device according to claim 10, wherein
the layer constituting said interface layer in contact with said reflectance control layer is made of SiO₂.

12. The nitride-based semiconductor laser device according to claim 9, wherein
the layer constituting said interface layer in contact with said alteration preventing layer contains the same metal element as said alteration preventing layer.

13. The nitride-based semiconductor laser device according to claim 12, wherein
the layer constituting said interface layer in contact with said alteration preventing layer is made of Al₂O₃.

14. The nitride-based semiconductor laser device according to claim 8, wherein
said nitride-based semiconductor element layer further has a light emitting layer, and
an optical film thickness of the layer constituting said interface layer is set to at least λ/4, where a wavelength of a laser beam emitted by said light emitting layer is λ.

15. The nitride-based semiconductor laser device according to claim 8, wherein
a thickness of the layer constituting said interface layer is larger than a thickness of each of the layers constituting said alteration preventing layer.

16. The nitride-based semiconductor laser device according to claim 1, wherein
each of the layers constituting said alteration preventing layer contains the same metal element.

17. The nitride-based semiconductor laser device according to claim 5, wherein
said second layer is made of AlON, and a nitrogen composition ratio in said second layer made of AlON is larger than an oxygen composition ratio.

18. The nitride-based semiconductor laser device according to claim 1, wherein
said nitride-based semiconductor element layer further has a light emitting layer, and
an optical film thickness of each of the layers formed by said dielectric layers constituting said alteration preventing layer is set to at most λ/4, where a wavelength of a laser beam emitted by said light emitting layer is λ.

19. The nitride-based semiconductor laser device according to claim 1, wherein
said low refractive index layer is made of an oxide or an oxynitride, and said high refractive index layer is made of a nitride or an oxynitride.

20. An optical pickup comprising:
a nitride-based semiconductor laser device including a nitride-based semiconductor element layer having a light emitting side facet and a light reflecting side facet, and a facet coating film including an alteration preventing layer formed on said light reflecting side facet and a reflectance control layer formed on said alteration preventing layer;
an optical system controlling emitted light of said nitride-based semiconductor laser device; and
a light detection portion detecting said emitted light, wherein
said reflectance control layer is formed by a high refractive index layer and a low refractive index layer which are alternately stacked,
said alteration preventing layer is constituted by stacking at least two layers, each of which is formed by a dielectric layer made of a nitride, an oxide or an oxynitride,
said alteration preventing layer has a first layer formed by a dielectric layer made of a nitride in contact with said light reflecting side facet, and
a thickness of each of the layers constituting said alteration preventing layer is smaller than that of said high refractive index layer and is smaller than that of said low refractive index layer.
